(19) United States
(12) Patent Application Publication
(10) Pub. No.: US 2022/0380885 A1
(43) Pub. Date: Dec. 1, 2022

(54) SPUTTER DEPOSITION APPARATUS AND METHOD

(71) Applicant: Dyson Technology Limited, Wiltshire (GB)

(72) Inventors: Michael Edward RENDALL, Newbury (GB); Robert Ian Joseph GRUAR, Swindon (GB)

(73) Assignee: Dyson Technology Limited, Wiltshire (GB)

(21) Appl. No.: 17/776,584

(22) PCT Filed: Nov. 10, 2020
(86) PCT No.: PCT/GB2020/052840

§ 371 Date: May 12, 2022

(30) Foreign Application Priority Data
Nov. 15, 2019 (GB) 1916624.8

(51) Int. Cl. C23C 14/34; C23C 14/50; C23C 14/54; C23C 14/35

(52) U.S. Cl. CPC C23C 14/3407; C23C 14/50; C23C 14/54; C23C 14/352

(57) ABSTRACT

Certain examples described herein relate to a sputter deposition apparatus including a substrate holder, a target loader, a plasma source to generate a plasma, and a magnet arrangement. The substrate holder is to position a substrate in a sputter deposition zone for sputter deposition of target material from a first target to the substrate in use. The target loader is to move a second target from a target priming zone into the sputter deposition zone for sputter deposition of target material from the second target to the substrate in use. The magnet arrangement configured to confine the plasma within the apparatus to the target priming zone and the sputter deposition zone. Within the target priming zone, a respective target is exposed to the plasma in use. The sputter deposition zone provides for sputter deposition of target material.

### TECHNICAL FIELD

The present invention relates to deposition, and more particularly, although not exclusively, to sputter deposition of a target material onto a substrate.

### BACKGROUND

Deposition is a process by which target material is deposited on a substrate. An example of deposition is thin film deposition in which a thin layer (typically from around a nanometre or even a fraction of a nanometre up to several micrometres or even tens of micrometres) is deposited on a substrate, such as a silicon wafer or web. An example technique for thin film deposition is Physical Vapor Deposition (PVD), in which target material in a condensed phase is vaporised to produce a vapor, which is then condensed onto a surface of the substrate. An example of PVD is sputter deposition, in which particles are ejected from the target as a result of bombardment by energetic particles, such as ions. In examples of sputter deposition, a sputter gas, which may be an inert gas such as Argon, is introduced into a vacuum chamber at low pressure, and the sputter gas is ionised using energetic electrons to create a plasma. Bombardment of the target by ions of the plasma eject target material which may then deposit on the substrate surface. Sputter deposition has advantages over other thin film deposition methods such as evaporation in that target materials may be deposited without the need to heat the target material, which may in turn reduce or prevent thermal damage to the substrate.

### SUMMARY

According to a first aspect of the present invention, there is provided a sputter deposition apparatus comprising:
a substrate-holding means to position a substrate in a sputter deposition zone for sputter deposition of target material from a first target to the substrate in use;
a target loading means to move a second target from a target priming zone into the sputter deposition zone for sputter deposition of target material from the second target to the substrate in use;
a plasma source to generate a plasma;
a magnet arrangement configured to confine the plasma within the apparatus to:
   the target priming zone, within which a respective target is exposed to the plasma in use; and
   the sputter deposition zone for sputter deposition of target material.

Confining the generated plasma in this way, to both the target priming and sputter deposition zones, may allow for more efficient use of generated plasma. In turn, a more energy-efficient sputter deposition process can be attained compared to known apparatuses and processes. For example, using the present apparatus for sputter deposition can mean that the targets can be primed by the generated plasma prior to being installed in the deposition zone. This can therefore reduce delays in the sputter deposition process, which would otherwise be caused by replacing and then priming fresh targets in the deposition zone. The present apparatus may also provide improved space-efficiency compared to known sputter deposition apparatuses, e.g. which use separate plasma sources, given the control provided by the magnet arrangement confining the plasma.

In some examples, the target loading means is arranged to move the second target into the sputter deposition zone in place of the first target. A new target may thus replace a target in situ, which may be “spent” e.g. having had more than a predetermined amount of target material sputtered therefrom.

In some examples, the target loading means is arranged to move the second target into the sputter deposition zone for sputter deposition of target material from the first and second targets to the substrate in use. Multiple targets may thus be located in the sputter deposition zone for sputter deposition of target material therefrom. The different targets may comprise different target materials, for example, such that a mixture of target materials may be sputtered and deposited onto the substrate.

In some examples, the target loading means is arranged to move the first target from the sputter deposition zone when moving the second target into the sputter deposition zone. The first target in situ may thus be completely replaced by the second target entering the sputter deposition zone. In other examples, e.g. mentioned above, the first target may remain in the deposition zone after the second target has been moved into the deposition zone. In some cases, e.g. after moving the first target from the sputter deposition zone and moving the second target into the sputter deposition zone, the target loading means is arranged remove the second target from the sputter deposition zone and to return the first target to the sputter deposition zone. In this way, different target materials may be alternately deposited onto the substrate, e.g. by alternating the target in the sputter deposition zone.

In some cases, the target loading means is arranged to move a third target from the sputter deposition zone when moving the second target into the sputter deposition zone. In this way, the target loading means may position more than one target (e.g. the first and second targets) in the deposition zone while removing another one (e.g. the third target) which may be spent.

In some examples, the magnet arrangement is configured to confine the plasma within the target priming zone to interact with at least part of a surface of a respective target in use. This interaction can provide for treatment of the surface of the target prior to the target entering the sputter deposition zone, which can improve the deposition of target material onto the substrate during deposition.

In some examples, within the target priming zone the plasma interacts with a respective target in an ablative process in use. Ablation of the target can allow for increased homogeneity and/or roughness of the target surface prior to deposition. This can improve uniformity and/or control of crystallinity of deposition of target material onto the substrate during the sputter deposition process.

In examples, the sputter deposition zone comprises a sputter deposition chamber. In examples, the target priming zone comprises a target priming chamber. The target priming chamber may be under at least partial vacuum in use.

In some examples, the target loading means comprises a target conveyor to convey the second target, in a first conveyance direction, between the target priming zone and the sputter deposition zone. The substrate-holding means may be arranged to guide the substrate, in a second conveyance direction, through the sputter deposition zone.

In examples, the first and second conveyance directions are substantially parallel to one another, substantially orthogonal to one another, or the first conveyance direction may be rotational.

In examples, the target loading means is configured to move the second target into the sputter deposition zone after the second target has spent at least a predetermined amount of time within the target priming zone. This may allow for a corresponding predetermined amount of priming, e.g. an amount of surface ablation, of the target to be attained.

In examples, the apparatus comprises a device having a sensor to detect a surface homogeneity of the second target. The target loading means may be configured to move the second target into the sputter deposition zone based on sensor data output by the sensor. This may allow for targets to enter the sputter deposition zone having at least a predetermined level of surface homogeneity, which in turn can improve the uniformity and/or control of crystallinity of target material deposited onto the substrate during the sputter deposition process.

In examples the substrate-holding means comprises a curved member. The curved member may comprise a roller.

In examples, the magnet arrangement is configured to confine the plasma in the form of a sheet.

In examples, the magnet arrangement comprises one or more magnetic elements. The apparatus may comprise a magnetic controller to control a magnetic field strength of the one or more of the magnetic elements. This may allow for adjustment of the plasma density at the substrate and/or the target material within the deposition zone, and hence allow for improved control over the sputter deposition. This may in turn allow for improved flexibility in the operation of the sputter deposition apparatus. Furthermore, the ability to control the magnetic field strength can similarly allow for adjustment of the plasma density at the substrate within the target priming zone. This may in turn allow for improved control of the target priming process and add to the flexibility in the operation of the sputter deposition apparatus, meaning that different types of substrate and/or target material may be utilised.

In examples, the plasma source is an inductively coupled plasma source. The plasma source may comprise one or more elongate antennae.

According to a second aspect of the present invention, there is provided a sputter deposition method comprising:
positioning a substrate, using a substrate-holding means, in a sputter deposition zone for sputter deposition of target material from a first target to the substrate;
moving a second target, using a target loading means, from a target priming zone into the sputter deposition zone for sputter deposition of target material from the second target to the substrate;
generating plasma using a plasma source;
confining said plasma, using a magnet arrangement, to:
   the target priming zone, within which a respective target is exposed to the plasma in use; and
   the sputter deposition zone for sputter deposition of target material.

In examples, the method comprises moving:
the second target into the sputter deposition zone in place of the first target;
the second target into the sputter deposition zone for sputter deposition of target material from the first and second targets to the substrate; or the first target from the sputter deposition zone when moving the second target into the sputter deposition zone.

Further features and advantages of the invention will become apparent from the following description, given by way of example only, which is made with reference to the accompanying drawings.

### BRIEF DESCRIPTION OF THE DRAWINGS

FIG. 1 is a schematic diagram of an apparatus according to an example;

FIG. 2 is a schematic diagram of the example apparatus of FIG. 1 including illustrative magnetic field lines;

FIG. 3 is a schematic diagram of a plan view of a portion of the example apparatus of FIGS. 1 and 2;

FIG. 4 is a schematic diagram of a plan view of the portion of the example apparatus of FIG. 3 including illustrative magnetic field lines;

FIG. 5 is a schematic diagram of a cross section of a magnetic element according to an example; and

FIG. 6 is a schematic flow diagram of a method according to an example.

### DETAILED DESCRIPTION

Details of apparatuses and methods according to examples will become apparent from the following description, with reference to the Figures. In this description, for the purpose of explanation, numerous specific details of certain examples are set forth. Reference in the specification to “an example” or similar language means that a particular feature, structure, or characteristic described in connection with the example is included in at least that one example, but not necessarily in other examples. It should further be noted that certain examples are described schematically with certain features omitted and/or necessarily simplified for ease of explanation and understanding of the concepts underlying the examples.

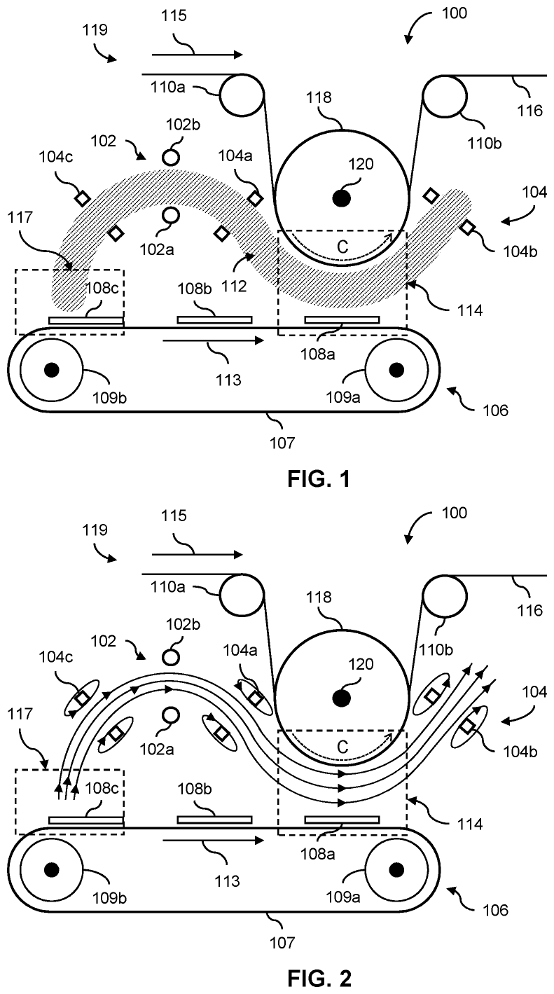

Referring to FIGS. 1 to 5, an example sputter deposition apparatus 100 is illustrated. The apparatus 100 is used for sputter deposition of target material 108 to a substrate 116. The apparatus 100 can thus be implemented in a wide number of industrial applications, such as those which utilise thin film deposition. Industrial applications include, for example (e.g.) the production of optical coatings, magnetic recording media, electronic semiconductor devices, LEDs, energy generation devices such as thin-film solar cells, and energy storage devices such as thin-film batteries. Therefore, while the context of the present disclosure may in some cases relate to the production of energy storage devices or portions thereof, it will be appreciated that the sputter deposition apparatus 100 and sputter deposition methods described herein are not limited to the production thereof.

Although not shown in the Figures for clarity, in some examples, it is to be appreciated that the apparatus 100 typically includes a housing (not shown), which in use is evacuated to a low pressure suitable for sputter deposition, for example 3×10⁻³ torr. Such a housing may be evacuated by a pumping system (not shown) to a suitable pressure (for example less than 1×10⁻⁵ torr). In use, a process or sputter gas, such as argon or nitrogen, is introduced into the housing using a gas feed system (not shown) to an extent such that a pressure suitable for sputter deposition is achieved, e.g. 3×10⁻³ torr.

Returning to the example illustrated in FIGS. 1 to 5, in broad overview, the apparatus 100 comprises a substrate-holding means 118, a target loading means 106, a plasma source 102, and a magnet arrangement 104.

The substrate-holding means 118 is arranged to position a substrate 116 in a sputter deposition zone 114. The substrate-holding means 118 may guide the substrate 116, e.g. a web of substrate, in a substrate conveyance direction 115. The substrate-holding means 118 may comprise a curved member 118 to guide the substrate 116 along a curved path (indicated by arrow C in FIGS. 1 and 2) for example.

The curved member 118 may be arranged to rotate about an axis 120, for example provided by an axle 120. In the example illustrated in FIG. 3, the axis 120 is also a longitudinal axis of the curved member 118. In some examples, the curved member 118 is a roller. In certain cases, the curved member 118 is provided by a substantially cylindrical drum or roller 118 of an overall substrate feed assembly 119. The substrate feed assembly 119 may be arranged to feed the substrate 116 onto and from the roller 118 such that the substrate 116 is carried by at least part of a curved surface of the roller 118. In some examples, the substrate feed assembly comprises a first roller 110a arranged to feed the substrate 116 onto the drum 118, and a second roller 110b arranged to feed the substrate 116 from the drum 118, after the substrate 116 has followed the curved path C. The substrate feed assembly 119 may be part of a “reel-to-reel” process arrangement (not shown), where the substrate 116 is fed from a first reel or bobbin (not shown) of substrate 116, passes through the apparatus 100, and is then fed onto a second reel or bobbin (not shown) to form a loaded reel of processed substrate (not shown).

In some examples, the substrate 116 is or at least comprises silicon or a polymer. In some examples, e.g. for the production of an energy storage device, the substrate 116 is or at least comprises nickel foil. It will be appreciated, however, that any suitable metal could be used instead of nickel, such as aluminium, copper or steel, or a metallised material including metallised plastics such as aluminium on polyethylene terephthalate (PET).

The plasma source 102, which may also be referred to as a “plasma generation arrangement” is arranged to generate plasma 112.

The plasma source 102 may be an inductively coupled plasma source, e.g. arranged to generate an inductively coupled plasma 112. The plasma source 102 shown in FIGS. 1 and 2 includes antennae 102a, 102b, through which appropriate radio frequency (RF) power may be driven by a radio frequency power supply system (not shown) to generate an inductively coupled plasma 112 from the process- or sputter gas in the housing (not shown). In some examples, plasma 112 is generated by driving a radio frequency current through the one or more antennae 102a, 102b, for example at a frequency between 1 MHz and 1 GHz; a frequency between 1 MHz and 100 MHz; a frequency between 10 MHz and 40 MHz; or, in some examples, at a frequency of approximately 13.56 MHz or multiples thereof. The RF power causes ionisation of the process- or sputter gas to produce plasma 112. Tuning the RF power driven through the one or more antennae 102a, 102b can affect the plasma density of the plasma 112 within the pre-treatment zone. Thus, by controlling the RF power at the plasma source 102, the pre-treatment process can be controlled. This may in turn allow for improved flexibility in the operation of the sputter deposition apparatus 100.

In some examples, the plasma source 102 is disposed remotely of the substrate-holding means 118. For example, the plasma source 102 may be disposed at a distance radially away from the curved member 118. In such cases, plasma 112 is generated remotely of the substrate-holding means 118.

The one or more antennae 102a, 102b of the plasma source 102 may be elongate antennae, and in some examples are substantially linear. In some examples, the one or more antennae 102a, 102b are elongate antennae and extend in a direction substantially parallel to the longitudinal axis 120 of the curved member 108 (e.g. the axis 120 of the roller 118 which passes through the origin of the radius of curvature of the roller 118). In the example of FIG. 1, the longitudinal axis 120 of the roller 118 is also the rotation axis of the roller 118. One or more of the elongate antennae 102a, 102b may be curved. For example, such curved elongate antennae 102a, 102b may follow the curvature of at curved surface of the curved member 118. In some cases, one or more of the curved elongate antennae 102a, 102b extend in a plane substantially perpendicular to the longitudinal axis 120 of the curved member 118.

In some examples, the plasma source 102 comprises two antennae 102a, 102b for producing an inductively coupled plasma 112. In some examples (e.g. as illustrated in FIG. 3), the antennae 102a, 102b are elongate and substantially linear and extend parallel to the longitudinal axis 120 (which may also be the rotation axis 120) of the curved member 118. The antennae 102a, 102b may extend substantially parallel to one another and may be disposed laterally from one another. This can allow for a precise generation of an elongate region of plasma 112 between the two antennae 102a, 102b, which can in turn help provide for precise confining of the generated plasma 112 to at least the deposition zone 114, as described in more detail below. In some examples, the antennae 120a, 120b is similar in length to the substrate-holding means 118, and accordingly similar to the width of the substrate 116 guided by the substrate-holding means 118. The elongate antennae 102a, 102b can provide for plasma 112 to be generated across a region having a length corresponding to the length of the substrate guide 118 (and hence corresponding to the width of the substrate 116), and hence can allow for plasma 112 to be available evenly or uniformly across the width of the substrate 116. As described in more detail below, this may in turn help provide for even or uniform sputter deposition.

The magnet arrangement 104 is configured to confine the plasma 112 (e.g. the plasma generated by the plasma generation arrangement 102) within the apparatus 100 to the sputter deposition zone 114, in order to provide for sputter deposition of target material 108 to the substrate 116 in use. In examples, the sputter deposition zone 114 comprises a sputter deposition chamber (e.g. a “housing” as described above; not shown in the Figures). For example, the sputter deposition chamber may be under at least partial vacuum. In some cases, an inert gas, such as Argon, is introduced into the sputter deposition chamber at low pressure and may be ionised. Bombardment of the target by ions of the plasma can eject target material 108 for deposition onto the substrate 116.

The substrate-holding means 118 is arranged to position the substrate 116 in the sputter deposition zone 114 for sputter deposition of target material from a first target 108a to the substrate 116. The target loading means 106 is arranged to move a second target 108b from a target priming zone 113 into the sputter deposition zone 114 for sputter deposition of target material from the second target 108b to the substrate 116.

The magnet arrangement 104 is also configured to confine the plasma 112, within the apparatus 100, to the target priming zone 113, within which a respective target is exposed to the plasma 112 in use. In some examples, the target priming zone 113 comprises a target priming chamber (similar to the described “housing”; not shown in the Figures). In use, the target priming chamber is typically under at least partial vacuum. In FIGS. 1 and 2, the sputter deposition zone 114 is located after the target priming zone 117, in a target conveyance direction 113. In use, this can allow for treatment of the targets 108a, 108b, 108c prior to deposition occurring, e.g. as “pre-treatment” or “priming” of a respective target. Such priming of a target 108 typically involves removing material from the surface of the target 108 which is to have material sputtered therefrom and deposited onto the substrate 116 during sputter deposition. The sputter deposition process may be improved by the target being treated or “primed” by the plasma 112 before deposition. For example, priming the target 108 can promote better adhesion of target material 108 to the substrate 116 during the deposition process within the sputter deposition zone 114. The sputter deposition may therefore, in turn, be performed more consistently. This may, for example, improve the consistency of the processed substrate, and may for example, reduce the need for quality control. Furthermore, the present setup can allow for more efficient use of generated plasma 112 and thus a more efficient sputter deposition process, but also in a space efficient way. For example, the same plasma source 102 can be used to both prime the targets 108a, 108b, 108c and provide for sputter deposition of the target material onto the substrate 116.

In use, the magnet arrangement 104 may confine the plasma 112 within the target priming zone 117 to interact with at least part of a surface of a respective target 108a, 108b, 108c. Interaction between the plasma 112 and the surface of the respective target 108a, 108b, 108c can treat the target 108a, 108b, 108c prior to the target 108a, 108b, 108c entering the sputter deposition zone 114. This can improve the deposition of target material 108 onto the substrate 116. In some cases, for example, the plasma 112 interacts with the respective target 108a, 108b, 108c in an ablative process within the target priming zone 117 in use. The plasma 112 may ablate the target surface as part of the treatment thereof, e.g. to remove material from the surface of the target 108 which may include impurities such as oxides and/or other inhomogeneities. Such inhomogeneities can originate when manufacturing the target. Such priming of the target 108 can therefore increase a homogeneity of the target surface. In turn, such priming can allow for more uniform deposition of target material 108 onto the substrate 116 when the target 108 reaches the sputter deposition zone 114. The sputter deposition can therefore, in turn, be performed more consistently. This can improve the consistency of the processed substrate and reduce the need for quality control.

Ablation as a mechanism of target priming (or “roughening”) typically depends on a sputtering threshold of the target being exceeded. For example, the sputtering threshold of the target may be a defined minimum energy threshold corresponding to the target material.

The sputtering threshold may be a defined amount of energy at which the energy transfer from a plasma ion to an atom of the target material equals the binding energy of a surface atom of the target material. In other words, sputtering (or ablation) of the target occurs when a plasma ion can transfer more energy into the target material than is required for an atom to break free from the target material surface. Below the sputtering threshold of the target material, however, target priming or roughening can occur via restructuring of the target material. For example, at plasma energies below the sputtering threshold of the target material, the transfer of energy from the plasma ions to the target material may cause bond-breaking and reformation, e.g. chemical bonds between atoms of the substrate material to break and reform. This can cause activation or roughening of the target surface without ablation.

In the example of FIGS. 1 and 2, the magnet arrangement 104 comprises magnetic elements 104a, 104b, 104c arranged to provide a confining magnetic field to confine, e.g. in some examples guide, plasma into the target priming and sputter deposition zones 114, 117. The magnet arrangement 104, e.g. the magnetic elements 104a, 104b, 104c, may be disposed outside a curve of the curved member 118.

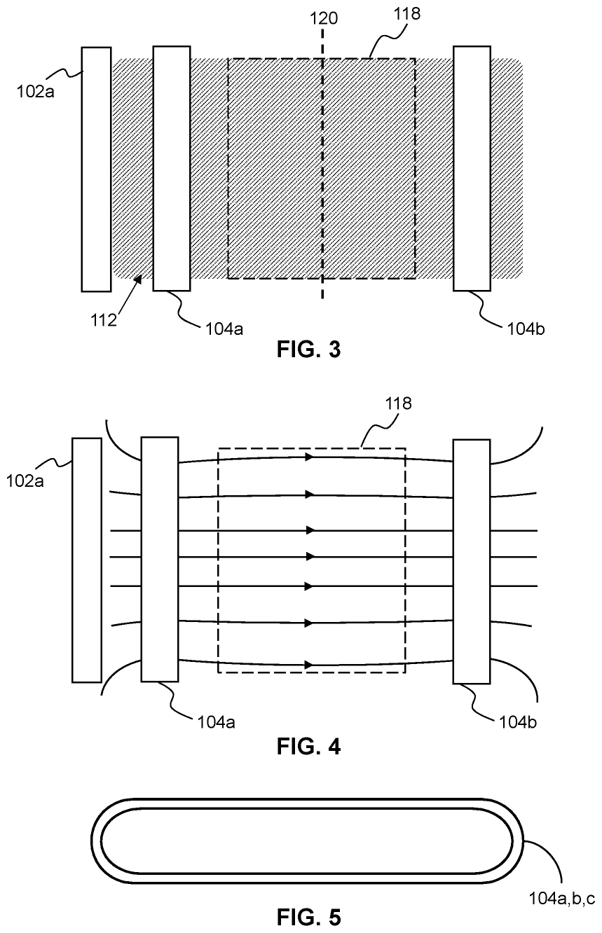

It will be appreciated that magnetic field lines may be used to describe the arrangement or geometry of a magnetic field. An example magnetic field provided by the example magnetic elements 104a, 104b, 104c is illustrated schematically in FIGS. 2 and 4, where magnetic field lines (indicated as is convention by arrowed lines) are used to describe the magnetic field provided in use.

The magnetic field lines being arranged to impinge on the target priming and sputter deposition zones 114, 117 confines the generated plasma 112 to the target priming and sputter deposition zones 114, 117. This can occur because the generated plasma 112 tends to follow the magnetic field lines. For example, ions of the plasma 112 within the confining magnetic field and with some initial velocity will experience a Lorentz force that causes the ion to follow a periodic motion around the magnetic field line. If the initial motion is not strictly perpendicular to the magnetic field, the ion follows a helical path centred on the magnetic field line. The plasma containing such ions therefore tends to follow the magnetic field lines and hence can be confined to, e.g. guided on, a path defined thereby. Accordingly, since the magnetic field lines are arranged to enter the target priming and sputter deposition zones 114, 117, the plasma 112 will hence be confined to, e.g. guided into, the target priming and sputter deposition zones 114, 117.

In some examples, the plasma 112 substantially conforms to a curvature of at least part of a curved surface of the curved member 118. For example, as shown in FIGS. 2 and 4, the magnetic field lines describing the confining magnetic field are each curved so as to substantially conform to the curvature of at least part of the curved surface of the curved member 118, e.g. so as to substantially follow the curve of the curved path C. In such examples, it will be appreciated that, in principle, the whole or entire magnetic field provided by the magnetic elements 104a, 104b, 104c typically includes portions which may be described by magnetic field lines which are not arranged to conform to the curvature of at least part of the curved surface of the curved member 118, e.g. follow the curve of the curved path C. Nonetheless, in such examples, the confining magnetic field provided, i.e. the part of the entire or whole magnetic field provided by the magnetic elements 104a, 104b, 104c that confines the plasma 112 into the target priming zone 114, is described by magnetic field lines that substantially conform to the curvature of at least part of the curved surface of the curved member 118.

In some examples, the magnetic field lines describing the confining magnetic field are arranged to conform to, e.g. follow, the curve of the curved member or roller 118 around a substantial or significant sector or portion of the curved member 118. For example, in use, the magnetic field lines may conform to the curve of the curved member 118 over all or a substantial part of the notional sector of the curved member 118 that carries or contacts the substrate 116. For example, the curved member 118 is typically substantially cylindrical in shape, and magnetic field lines describing the confining magnetic field can be arranged to follow the curve of the curved member 118 around at least about 1/16 or at least about ⅛ or at least about ¼ or at least about ½ of the circumference of the curved member 118. For example, the magnetic field lines describing the confining magnetic field in FIG. 2 follow a curved path around about at least ¼ of the circumference of the curved member 118. Thus, in examples, the plasma 112 substantially conforms to a curvature of around at least about 1/16 or at least about ⅛ or at least about ¼ or at least about ½ of the curved surface, e.g. circumference, of the curved member 118.

In examples, the one or more magnetic elements 104a, 104b, 104c are arranged such that the plasma source 102 separates a first subset of the magnetic elements 104a, 104b, 104c from a second subset of the magnetic elements 104a, 104b, 104c. For example, FIG. 1 shows one of the magnetic elements 104c separated from the other magnetic elements 104a, 104b by the plasma source 102 located therebetween. The first subset 104c of the magnetic elements 104a, 104b, 104c are configured to confine the plasma 112 from the plasma source 102 to the target priming zone 117, for example. The second subset 104a, 104b of the magnetic elements 104a, 104b, 104c are configured to confine the plasma 112 from the plasma source 102 to the sputter deposition zone 114, for example. Together, the magnetic elements 104a, 104b, 104c are configured to confine the plasma 112 to the target priming and sputter deposition zones 114, 117 as described herein.

Where the curve of the curved path C is referenced in certain examples, this can be understood as the degree to which the path along which the substrate guide 118 carries the substrate 116 is curved. For example, the curved member 118, such as a drum or roller, carries the substrate 116 along the curved path C. In such examples, the curve of the curved path C results from the degree to which the curved surface of the curved member 118 that carries the substrate 116 is curved, e.g. deviates from a flat plane. In other words, the curve of the curved path C may be understood as the degree to which the curved path C that the curved member 118 causes the substrate 116 to follow is curved. To substantially follow the curve of the curved path C may be understood as to substantially conform to or replicate the curved shape of the curved path C. For example, magnetic field lines may follow a curved path that has a common centre of curvature with the curved path C, but which has a different (in the illustrated examples larger) radius of curvature than the curved path C. For example, the magnetic field lines may follow a curved path that is substantially parallel to, but radially offset from, the curved path C of the substrate 116. In examples, the magnetic field lines follow a curved path that is substantially parallel to, but radially offset from, the curved surface of the curved member 118. For example, the magnetic field lines describing the confining magnetic field in FIG. 2 follow a curved path, at least in the sputter deposition zone 114, that is substantially parallel to, but radially offset from, the curved path C, and hence which substantially follows the curve of the curved path C.

The magnetic field lines describing the confining magnetic field may be arranged to follow the curve of the curved path C around a substantial or significant sector or portion of the curved path C. For example, the magnetic field lines may follow the curve of the curved path C over all or a substantial part of the notional sector of the curved path C, over which the substrate 116 is guided by the curved member 118. In examples, the curved path C represents a portion of a circumference of a notional circle, and magnetic field lines characterising the confining magnetic field are arranged to follow the curve of the curved path C around at least about 1/16 or at least about ⅛ or at least about ¼ or at least about ½ of the circumference of the notional circle.

Confining the generated plasma 112 to substantially conform to a curvature of at least part of a curved surface of the curved member 118, e.g. follow a curve of the curved path C, may allow for more uniform distribution of plasma density at the substrate 116 at least in a direction around the curved surface of the curved member 118, e.g. the curve of the curved path C. This may in turn allow for a more uniform sputter deposition onto the substrate 116 in a direction around the curved member 118, e.g. the curved path C. The sputter deposition may therefore, in turn, be performed more consistently. This can improve the consistency of the processed substrate and reduce the need for quality control compared to, e.g., magnetron type sputter deposition apparatuses where the magnetic field lines describing the magnetic field produced thereby loop tightly into and out of a substrate, and hence do not allow for uniform distribution of plasma density at the substrate.

Alternatively, or additionally, confining the generated plasma 112 to substantially conform to a curvature of at least part of a curved surface of the curved member 118, e.g. follow a curve of the curved path C, may allow for an increased area of the substrate 116 to be exposed to the plasma 112, and hence for an increased area in which sputter deposition may be effected. This can allow for the substrate 116 to be fed through a reel-to-reel type apparatus at a faster rate for a given degree of deposition, and hence allow for more efficient sputter deposition.

In some examples, the magnet arrangement (or “magnetic confining arrangement”) 104 comprises at least two magnetic elements 104a, 104b arranged to provide a magnetic field. In some cases, the at least two magnetic elements 104a, 104b are arranged such that a region of relatively high magnetic field strength defined between the at least two magnetic elements 104a, 104b is in the form of a sheet. The magnet arrangement 104 may thus be configured to confine the plasma 112 in the form of a sheet, that is, in a form in which the depth (or thickness) of the plasma 112 is substantially less than its length or width. The thickness of the sheet of plasma 112 may be substantially constant along the length and width of the sheet. The density of the sheet of plasma 112 may be substantially uniform in one or both of its width and length directions.

In some examples, a region of relatively high magnetic field strength provided between the at least two magnetic elements 104a, 104b substantially conforms to the curvature of at least part of the curved surface of the curved member 118, e.g. substantially follows the curve of the curved path C.

In the example illustrated schematically in FIGS. 1 and 2, two magnetic elements 104a, 104b are located on opposite sides of the drum 118 to one another, and each is disposed above a lowermost portion of the drum 118 (in the sense of FIG. 1). The two magnetic elements 104a, 104b confine the plasma 112 to conform to the curvature of at least part of the curved surface of the curved member 118, e.g. follow the curve of the curved path C, on both sides of the curved member 118. For example, the plasma 112 follow the curve of the curved path C on a feed-on side, where the substrate 116 is fed onto the curved member 118, and a feed-off side where the substrate 116 is fed off of the curved member 118. Having at least two magnetic elements may therefore provide for a (further) increase in the area of the substrate 116 that is exposed to plasma 112 in the sputter deposition zone 114, and hence increased area in which sputter deposition may be effected. This can allow for the substrate 116 to be fed through a reel-to-reel type apparatus at a (still) faster rate for a given degree of deposition, and hence allow for more efficient sputter deposition, for example.

As described, in some examples a first subset of the magnetic elements 104a, 104b, 104c may be disposed on an opposite side of the plasma source 102 to a second subset of the magnetic elements 104a, 104b, 104c. For example, the magnet arrangement 104 may comprise at least three magnetic elements 104a, 104b, 104c arranged to provide the magnetic field. In examples, at least two of the at least three magnetic elements 104a, 104b, 104c, shown as the two magnetic elements 104a, 104b in the Figures, are arranged to provide the magnetic field which impinges on the sputter deposition zone 114, as described in examples above. At least one of the at least three magnetic elements 104a, 104b, 104c, shown as the magnetic element 104c in the Figures, is arranged to provide the magnetic field which impinges on the target priming zone 117. The at least two magnetic elements 104a, 104b of the at least three magnetic elements 104a, 104b, 104c may therefore be configured to confine the plasma 112 to at least the sputter deposition zone 114, whereas the at least one magnetic element 104c of the at least three magnetic elements 104a, 104b, 104c may be configured to confine the plasma 112 to at least the target priming zone 117. Together, the at least three magnetic elements 104a, 104b, 104c are configured to confine the plasma 112 to the target priming and sputter deposition zones 114, 117 as described herein.

In some examples, one or more of the magnetic elements 104a, 104b, 104c is an electromagnet 104a, 104b, 104c. The apparatus 100 may comprise a magnetic controller (not shown) to control a magnetic field strength of, e.g. provided by, one or more of the electromagnets 104a, 104b, 104c. This may allow for the arrangement of the magnetic field lines describing the confining magnetic field to be controlled. In turn, the plasma density at the substrate 116 and/or the target material 108 within the sputter deposition zone 114 can be adjusted, and hence control over the sputter deposition can be improved. This may in turn allow for improved flexibility in the operation of the sputter deposition apparatus 100. Furthermore, controlling the magnetic field strength provided by the magnet arrangement 104 can similarly allow for adjustment of the plasma density at the substrate 116 within the target priming zone 117. This may in turn allow for improved control of the target priming process, e.g. an amount of ablation, and add to the flexibility in the operation of the sputter deposition apparatus 100 such that different types of substrate and/or target materials may be utilised. As well as plasma density within the target priming zone 117, controlling the arrangement of the magnetic field lines describing the confining magnetic field provided by the magnet arrangement 104, allows for a shape of the plasma 112 to be controlled within the target priming zone 117. This may in turn allow for the dimensions of the target priming zone 117 to be adjusted, e.g. the size of the region of substrate 116 that is exposed to the plasma at any one time in use. Thus, yet further flexibility in the operation of the sputter deposition apparatus 100 can be provided such that different types of substrate and/or target materials may be utilised.

In some examples, one or more of the magnetic elements 104a, 104b, 104c is provided by a solenoid 104a, 104b, 104c. In examples, the solenoid 104a, 104b, 104c is elongate in cross section. For example, the solenoid 104a, 104b, 104c may be elongate in cross section in a direction substantially parallel to an axis of rotation of the curved member 118, e.g. roller 118. Each solenoid 104a, 104b, 104c may define an opening through which plasma 112 passes (is confined) in use. As per the example illustrated schematically in FIGS. 1 and 2, there are three solenoids 104a, 104b, 104c and each solenoid 104a, 104b, 104c is angled so that a region of relatively high magnetic field strength is provided between the solenoids 104a, 104b, 104c, e.g. to substantially follow the curve of the curved path C. In such a way, as illustrated in FIG. 1, in one direction the generated plasma 112 passes through a first of the solenoids 104a, under the drum 118 (in the sense of FIG. 1) into the deposition zone 114, and up towards and through the second of the solenoids 104b. In another direction the generated plasma 112 passes through the first of the solenoids 104a, away from the drum 118 towards and through the third of the solenoids 104c, and into the target priming zone 117.

Although only three magnetic elements 104a, 104b, 104c are shown in FIGS. 1 and 2, it will be appreciated that further magnetic elements (not shown), e.g. further such solenoids, may be placed along the path of the plasma 112. This may allow for strengthening of the confining magnetic field and hence for precise confining of the plasma. Additionally, or alternatively, this may allow for more degrees of freedom in the control of the confining magnetic field.

As shown in FIGS. 1 and 2, and described above, the sputter deposition apparatus 100 comprises a target loading means 106 arranged to move a second target 108b from the target priming zone 117 into the sputter deposition zone 114 for sputter deposition of target material from the second target 108b to the substrate 116 in use. The deposition zone 114 is typically located between a portion of the target loading means 106 and the substrate-holding means 118 in such cases. For example, the portion of the target loading means 106 and the substrate-holding means 118 are spaced apart from one another such that the deposition zone 114 is formed between them. The deposition zone 114 may be taken as the area or volume in the apparatus 100, e.g. between the substrate-holding means 118 and the said portion of the target loading means 106, in which sputter deposition from the target material 108 onto the substrate 116 occurs in use.

In examples, the target loading means 106 comprises a target conveyor 107 to convey the second target 108b, in a target conveyance direction 113, between the target priming zone 117 and the sputter deposition zone 114. The target material 108 may be a material based on which the sputter deposition onto the substrate 116 is to be performed. For example, the target material 108 is, or comprises, material that is to be deposited onto the substrate 116 by sputter deposition.

In examples, the target loading means 106 is arranged to move the second target 108b into the sputter deposition zone 114 in place of the first target 108a, e.g. already in the sputter deposition zone 114. For example, the second target 108b is loaded on top of the first target 108a to effectively replace the first target 108a for the purpose of sputtering. Alternatively, the first and second targets 108a, 108b may both be positioned in the sputter deposition zone 114 for sputtering of both targets 108a, 108b simultaneously. For example, the target loading means 106 is arranged to move the second target 108b into the sputter deposition zone 114 for sputter deposition of target material from the first and second targets 108a, 108b to the substrate 116 in use.

In some examples, the target loading means 106 is arranged to move the first target 108a from the sputter deposition zone 114 when moving the second target 108b into the sputter deposition zone 114. For example, the target 108a already in the deposition zone 114 is removed from the deposition zone 114 when the new target 108b is loaded into the deposition zone 114 by the target loading means 106. In certain cases, the target loading means is arranged to remove the second target 108b from the sputter deposition zone 114 and to return the first target 108a to the sputter deposition zone 114. For example, this involves alternating deposition of different target materials, e.g. by alternating deposition of the first and second targets 108a, 108b.

In examples, the target loading means 106 is arranged to move a third target 108c from the sputter deposition zone 114 when moving the second target 108b into the sputter deposition zone 114. For example, more than one target (e.g. the first and second targets 108a, 108b) is positioned in the deposition zone by the target loading means 106 while another, e.g. spent, target 108c is removed therefrom.

In examples, the target loading means 106 is configured to move the second target 108b into the sputter deposition zone 114 after the second target 108b has spent at least a predetermined amount of time within the target priming zone 117. The amount of time a target 108 spends within the target priming zone 117 may correspond with an amount of priming, e.g. an amount of surface ablation, of the target 108 attained. The predetermined amount of time may thus correspond with a desired amount of priming for the second target 108b.

In examples, the apparatus 100 comprises a device having a sensor to detect a surface homogeneity of the second target 108b. The target loading means 106 may be configured to move the second target 108b into the sputter deposition zone 114 based on sensor data output by the sensor.

In examples, the target conveyance direction 113 and the substrate conveyance direction 115 are substantially parallel to one another. For example, as shown in FIGS. 1 and 2, the target conveyor 107 conveys the targets 108a, 108b, 108c in a direction parallel to that of the substrate 116 being conveyed by the substrate-holding means 118. In other examples, the target and substrate conveyance directions (or first and second conveyance directions) 113, 115 are substantially orthogonal to one another. For example, instead of the target conveyance direction 113 being right-to-left in FIG. 1, the target conveyance direction 113 may instead run into or out of the page. Alternatively, the substrate feed assembly 119 of FIGS. 1 and 2 may be rearranged so that the substrate conveyance direction 115 runs into or out of the page while the target conveyance direction 113 continues to run left-to-right.

In certain cases, the target conveyance direction 113 is rotational. For example, the target loading means 106 comprises a rotating target conveyor 107 arranged to convey the targets 108a, 108b, 108c in an elliptical, e.g. circular, path. The elliptical path may be described in a plane below the substrate-holding means 108, for example. Alternatively, the target conveyor 107 describes the elliptical path and convey the targets 108a, 108b, 108c without rotation of the target conveyor 107 about an axis. For example, the target conveyor 107 instead travels in an elliptical path described in a plane below the substrate-holding means 108.

In some examples, e.g. for the production of an energy storage device, the target material 108 is or comprises (or is or comprises a precursor material for) a cathode layer of an energy storage device, such as a material which is suitable for storing lithium ions, e.g. lithium cobalt oxide, lithium iron phosphate or alkali metal polysulphide salts. Additionally, or alternatively, the target material 108 is or comprises (or is or comprises a precursor material for) an anode layer of an energy storage device, such as lithium metal, graphite, silicon or indium tin oxides. Additionally, or alternatively, the target material 108 is or comprises (or is or comprises a precursor material for) an electrolyte layer of an energy storage device, such as a material which is ionically conductive, but which is also an electrical insulator, e.g. lithium phosphorous oxynitride (LiPON). For example, the target material 108 is, or comprises, LiPO as a precursor material for the deposition of LiPON onto the substrate 116, e.g. via reaction with nitrogen gas in the region of the target material 108.

In some examples, the magnet arrangement 104, e.g. comprising one or more magnetic elements 104a, 104b, 104c, is configured to confine the plasma 112 in the form of a sheet. For example, the magnet arrangement 104 is arranged to provide the magnetic field to confine the plasma 112 in the form of a sheet. In some examples, the magnet arrangement 104 is configured to confine the plasma 112 in the form of a sheet having a substantially uniform density, e.g. at least in the deposition zone 114 and/or target priming zone 117. In certain cases, the magnet arrangement 104 is configured to confine the plasma 112 in the form of a curved sheet.

For example, as illustrated in FIGS. 4 and 5, in some examples one or more of the solenoids 104a, 104b, 104c is elongate in a direction substantially perpendicular to a direction of the magnetic field lines produced internally thereof in use. For example, as perhaps best seen in FIGS. 3 to 5, the solenoids 104a, 104b, 104c each have an opening via which plasma 112 is confined in use (through which plasma 112 passes in use), where the opening is elongate in a direction substantially parallel to a longitudinal axis 120 of the curved member 118. As perhaps best seen in FIGS. 3 and 4, the elongate antennae 102a, 102b extend parallel to and in line with the solenoids 104a, 104b, 104c. As described above, plasma 112 may be generated along the length of the elongate antennae 102a, 102b, and the elongate solenoids 104a, 104c confine, e.g. guide, the plasma 112 in a direction away from the elongate antennae 102a, 102b, and through the respective elongate solenoids 104a, 104c.

The plasma 112 may be confined, e.g. guided, from the elongate antennae 102a, 102b by the elongate solenoids 104a, 104c in the form of a sheet. That is, in a form in which the depth (or thickness) of the plasma 112 is substantially less than its length or width. The thickness of the sheet of plasma 112 may be substantially constant along the length and width of the sheet. The density of the sheet of plasma 112 may be substantially uniform in one or both of its width and length directions. The plasma 112, in the form of a sheet, may be confined by the magnetic field provided by the solenoids 104a, 104b, 104c around the curved member 118 so as to substantially conform to the curvature of a curved surface of the curved member 118, e.g. follow the curve of the curved path C, into the deposition zone 114. The plasma 112 may thereby be confined in the form of a curved sheet in some cases, as referenced above. The thickness of such a curved sheet of plasma 112 may be substantially constant along the length and width of the curved sheet. The plasma 112 in the form of a curved sheet may have a substantially uniform density, for example the density of the plasma 112 in the form of a curved sheet is substantially uniform in one or both of its length and width.

Confining the plasma in the form of a curved sheet can allow for an increased area of the substrate 116 carried by the curved member 118 to be exposed to the plasma 112, and hence for an increased area in which sputter deposition may be effected. This can allow, for example, for the substrate 116 to be fed through a reel-to-reel type apparatus at a (still) faster rate for a given degree of deposition, and hence for more efficient sputter deposition.

Confining the plasma 112 in the form of a curved sheet, for example a curved sheet having a substantially uniform density (e.g. at least in the sputter deposition zone 114) alternatively or additionally allows for a more uniform distribution of plasma density at the substrate 116, e.g. in both of a direction around the curve of the curved member 118, and over the length of the curved member 118. This can in turn allow for a more uniform sputter deposition onto the substrate 116, e.g. in a direction around the surface of the curved member 118 and across the width of the substrate 116. The sputter deposition can therefore, in turn, be performed more consistently. The consistency of the processed substrate can thus be improved, and the need for quality control reduced, compared to, for example, magnetron type sputter deposition apparatuses where the magnetic field lines characterising the magnetic field produced thereby loop tightly into and out of a substrate, and hence do not allow to provide uniform distribution of plasma density at the substrate.

In some examples, the confined plasma 112 is, at least in the deposition zone 114, high density plasma. For example, the confined plasma 112 (in the form of a curved sheet or otherwise) has, at least in the deposition zone 114, a density of 10¹¹ cm⁻³ or more. Plasma 112 of high density in the deposition zone 114 can allow for effective and/or high rate sputter deposition.

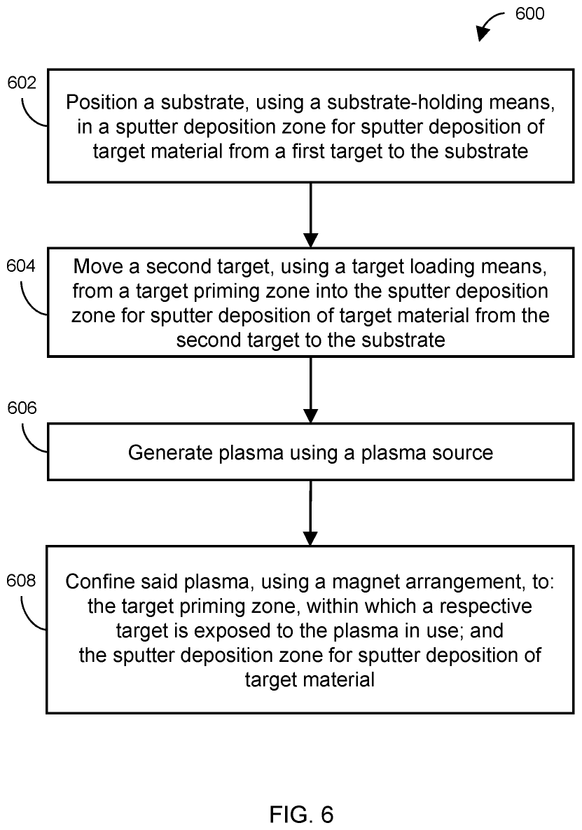

Referring to FIG. 6, an example sputter deposition method 600 is illustrated in a flow diagram. In the method 600, a substrate is positioned, using a substrate-holding means, in a sputter deposition zone for sputter deposition of target material from a first target to the substrate. A second target is moved, using a target loading means, from a target priming zone into the sputter deposition zone for sputter deposition of target material from the second target to the substrate. Plasma is generated, using a plasma source, and confined by a magnet arrangement to target priming and sputter deposition zones. In the target priming zone, a respective target is exposed to the plasma and in the sputter deposition zone, e.g. located after the target priming zone in the target conveyance direction, sputter deposition of target material (to the substrate) is provided for.

The first and second targets, the target material, the substrate, the substrate-holding means, the plasma source, the magnet arrangement, the target priming zone, and the sputter deposition zone, may be those of any of the examples described above with reference to FIGS. 1 to 5. In some examples, the method may be performed by the apparatus 100 described with reference to FIGS. 1 to 5.

The method involves, in step 602, positioning a substrate, using a substrate-holding means, in a sputter deposition zone for sputter deposition of target material from a first target to the substrate. For example, the substrate is guided by the substrate-holding means, e.g. curved member, 118 described above with reference to FIGS. 1 to 5.

In step 604, the method comprises moving a second target, using a target loading means, from a target priming zone into the sputter deposition zone for sputter deposition of target material from the second target to the substrate. For example, the second target is moved by the target loading means 106 described above with reference to FIGS. 1 to 5.

In step 606, the method comprises generating plasma using a plasma source. For example, the plasma is generated by the plasma generation arrangement 102 described above with reference to FIGS. 1 to 5.

In step 608, the method comprises confining the plasma, using a magnet arrangement, to a target priming zone and to a sputter deposition zone. For example, the plasma is confined by the magnet arrangement 104 described above with reference to FIGS. 1 to 5. Within the target priming zone, a respective target is exposed to the plasma. The sputter deposition zone provides for sputter deposition of target material to the substrate.

As mentioned, confining the generated plasma in this way can allow for more efficient use of generated plasma and thus a more efficient sputter deposition process, but also in a space-efficient manner. For example, confining the generated plasma in this way allows the same plasma source to be used for both priming the target(s) and providing for sputter deposition of target material 108 thereto.

In some cases, the method 600 involves moving the second target into the sputter deposition zone in place of the first target. Alternatively, the second target is moved into the sputter deposition zone for sputter deposition of target material from the first and second targets to the substrate, e.g. from both targets simultaneously. As a further alternative, the first target may be moved from the sputter deposition zone when moving the second target into the sputter deposition zone. Such examples are described in more detail above with reference to FIGS. 1 to 5.

The above examples are to be understood as illustrative examples of the invention. Further embodiments are envisaged. For example, many of the described examples utilise a curved member for guiding the substrate. The curved member, e.g. a roller or drum, may form part of, or work with, a roll-to-roll system for conveying the substrate. In certain cases, the curved member may not be a roller as such but may nonetheless define a curved path along which the substrate can be conveyed. However, although in some instances a curved substrate-holding means is preferable, embodiments are also envisaged in which this is not the case, e.g. where a roll-to-roll system is not implemented. Such embodiments of the sputter deposition apparatus or method may thus be implemented in systems utilising sheet-to-sheet and/or substrate-supported laser lift technology as described in KR20130029488, for example.

It is to be understood that any feature described in relation to any one example may be used alone, or in combination with other features described, and may also be used in combination with one or more features of any other of the examples, or any combination of any other of the examples. Furthermore, equivalents and modifications not described above may also be employed without departing from the scope of the invention, which is defined in the accompanying claims.

1. A sputter deposition apparatus comprising:
a substrate-holding means to position a substrate in a sputter deposition zone for sputter deposition of target material from a first target to the substrate in use;
a target loading means to move a second target from a target priming zone into the sputter deposition zone for sputter deposition of target material from the second target to the substrate in use;
a plasma source to generate a plasma;
a magnet arrangement configured to confine the plasma within the apparatus to:
the target priming zone, within which a respective target is exposed to the plasma in use; and
the sputter deposition zone for sputter deposition of target material.

2. The sputter deposition apparatus according to claim 1, wherein the target loading means is arranged to move the second target into the sputter deposition zone in place of the first target.

3. The sputter deposition apparatus according to claim 1, wherein the target loading means is arranged to move the second target into the sputter deposition zone for sputter deposition of target material from the first and second targets to the substrate in use.

4. The sputter deposition apparatus according to claim 1, wherein the target loading means is arranged to move the first target from the sputter deposition zone when moving the second target into the sputter deposition zone.

5. The sputter deposition apparatus according to claim 4, wherein the target loading means is arranged remove the second target from the sputter deposition zone and to return the first target to the sputter deposition zone.

6. The sputter deposition apparatus according to claim 1, wherein the target loading means is arranged to move a third target from the sputter deposition zone when moving the second target into the sputter deposition zone.

7. The sputter deposition apparatus according to claim 1, wherein the magnet arrangement is configured to confine the plasma within the target priming zone to interact with at least part of a surface of a respective target in use.

8. The sputter deposition apparatus according to claim 1, wherein within the target priming zone the plasma interacts with a respective target in an ablative process in use.

9. The sputter deposition apparatus according to claim 1, wherein the sputter deposition zone comprises a sputter deposition chamber.

10. The sputter deposition apparatus according to claim 1, wherein the target priming zone comprises a target priming chamber.

11. The sputter deposition apparatus according to claim 10, wherein the target priming chamber is under at least partial vacuum in use.

12. The sputter deposition apparatus according to claim 1, wherein the target loading means comprises a target conveyor to convey the second target, in a first conveyance direction, between the target priming zone and the sputter deposition zone.

13. The sputter deposition apparatus according to claim 12, wherein the substrate-holding means is arranged to guide the substrate, in a second conveyance direction, through the sputter deposition zone.

14. The sputter deposition apparatus according to claim 13, wherein:
the first and second conveyance directions are substantially parallel to one another;
the first and second conveyance directions are substantially orthogonal to one another; or
the first conveyance direction is rotational.

15. The sputter deposition apparatus according to claim 1, wherein the target loading means is configured to move the second target into the sputter deposition zone after the second target has spent at least a predetermined amount of time within the target priming zone.

16. The sputter deposition apparatus according to claim 1, wherein the apparatus comprises a device having a sensor to detect a surface homogeneity of the second target, wherein the target loading means is configured to move the second target into the sputter deposition zone based on sensor data output by the sensor.

17. The sputter deposition apparatus according to claim 1, wherein the substrate-holding means comprises a curved member.

18. The sputter deposition apparatus according to claim 17, wherein the curved member comprises a roller.

19. The sputter deposition apparatus according to claim 1, wherein the magnet arrangement is configured to confine the plasma in the form of a sheet.

20. The sputter deposition apparatus according to claim 1, wherein the magnet arrangement comprises one or more magnetic elements.

21. The sputter deposition apparatus according to claim 20, wherein the apparatus comprises a magnetic controller to control a magnetic field strength of the one or more of the magnetic elements.

22. The sputter deposition apparatus according to claim 1, wherein the plasma source is an inductively coupled plasma source.

23. The sputter deposition apparatus according to claim 1, wherein the plasma source comprises one or more elongate antennae.

24. A sputter deposition method comprising:
positioning a substrate, using a substrate-holding means, in a sputter deposition zone for sputter deposition of target material from a first target to the substrate;
moving a second target, using a target loading means, from a target priming zone into the sputter deposition zone for sputter deposition of target material from the second target to the substrate;
generating plasma using a plasma source;
confining said plasma, using a magnet arrangement, to:
the target priming zone, within which a respective target is exposed to the plasma in use; and
the sputter deposition zone for sputter deposition of target material.

25. The sputter deposition method according to claim 24, comprising moving:
the second target into the sputter deposition zone in place of the first target;
the second target into the sputter deposition zone for sputter deposition of target material from the first and second targets to the substrate; or
the first target from the sputter deposition zone when moving the second target into the sputter deposition zone.
